(19) United States
(12) Patent Application Publication
(10) Pub. No.: US 2007/0054510 A1
(43) Pub. Date: Mar. 8, 2007

(54) System and method for shielded coaxial cable attachment

(76) Inventor: Russell Price, Anaheim Hills, CA (US)

Correspondence Address: David L. Henty;MYERS DAWES ANDRAS & SHERMAN LLP, Suite 1150, 19900 MacArthur Boulevard, Irvine, CA, 92612, US

(21) Appl. No.: 11/512,970

(22) Filed: Aug. 30, 2006

Related U.S. Application Data
(60) Provisional application No. 60/713,698, filed on Sep. 2, 2005.

(51) Int. Cl. H05K 1/00

(52) U.S. Cl. 439/63

(57) ABSTRACT

A coaxial connection system and method for transferring radio frequency signals between a coaxial cable and printed circuit board is disclosed. A connection device fits into the edge of a printed circuit card and is attached to the printed circuit board. A hole in the connection device provides support for the coaxial cable as well as providing an interface for a cover to prevent emission of signals from the printed circuit board.

### RELATED APPLICATION

This application claims the benefit of U.S. provisional patent application Ser. No. 60/713,698, filed on Sep. 2, 2005, incorporated herein by reference in its entirety.

### FIELD OF THE INVENTION

The present invention relates to systems and methods for connection of coaxial cables to conductors on a printed circuit board.

### BACKGROUND, PRIOR ART AND RELATED INFORMATION

Coaxial cable is used widely in system configurations where microwave and radio signals are processed. Coaxial cables are terminated using connectors and direct attachment. Connectors offer a reliable means of connection but are often costly and introduce additional signal losses. Direct attachment of coaxial cable eliminates cost and the added signal losses but introduces several factors that affect the reliability of the connection and signal integrity. Soldered connections are susceptible to radiated emissions and need to withstand the imposed environmental conditions to insure connection integrity.

Accordingly, a need exists for an improved system and method for the connection of a coaxial cable to a printed circuit board while preventing radiated emissions.

### SUMMARY OF THE INVENTION

The present invention provides a system and method for the connection of a coaxial cable to a conductor on a printed circuit board and the ability to prevent parasitic radiation by the inclusion of a shield that mates directly to the connection device.

In a preferred embodiment, the present invention provides a device for connecting a coaxial cable to a printed circuit board, the device comprising a connector comprising an electrically conductive element having a receptacle that captures an end of the coaxial cable for connecting the coaxial cable to a conductor on the printed circuit board, and a shield that mates directly to the connector and the printed circuit board, to prevent parasitic radiation.

In another embodiment, the present invention employs a connection device comprising a single piece metal design that captures the coaxial cable within a circular opening. The connection device attaches to a printed circuit board with fasteners or by direct solder attachment to the top surface of a printed circuit board and provides a surface for an external cover to encapsulate the radiated emissions. The present connection device can be used for a variety of coaxial cables by varying the hole diameter and connection device dimensions and can accommodate both stripline and microstrip structures contained in a printed circuit board.

Further features and aspects of the invention are described in the following detailed description.

### BRIEF DESCRIPTION OF THE DRAWINGS

FIG. 1 is an exploded view showing the connecting device in a preferred embodiment of the invention.

FIG. 2 is an assembled view of the connecting device of FIG. 1.

FIG. 3 is a cross sectional view of the connecting device of FIG. 1.

### DETAILED DESCRIPTION OF THE INVENTION

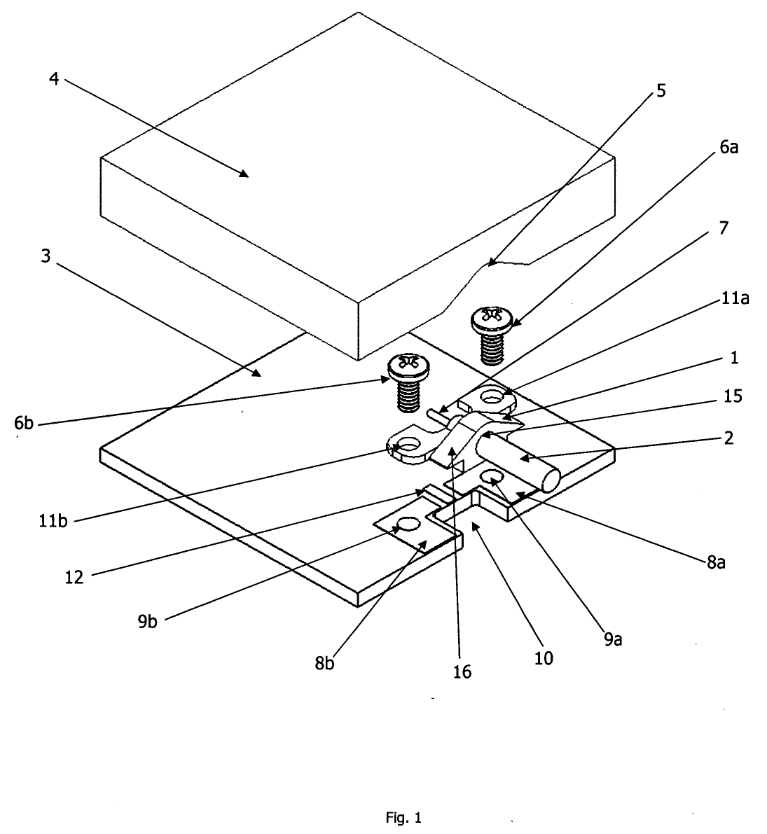

FIG. 1 is an exploded view showing the coaxial cable 2, printed circuit board 3, emission cover 4 and the connection device 1 that is used to connect the end of the coaxial cable 2 to the printed circuit board and provide an interface 16 to the emission cover 4. The end of the coaxial cable 2 is bared in order to reveal the center conductor 7 of the coaxial cable 2. In the example described, the center conductor 7 of the coaxial cable 2 is attached to the microstrip conductor 12 on the printed circuit board 3.

The coaxial cable 2 is fed through a circular hole 15 in the connection device 1. The circular hole is designed to capture the coaxial cable 2 and locate the center conductor 7 of the coaxial cable 2 relative to the microstrip conductor 12 on the printed circuit board to allow for a sufficient solder joint to connect.

The printed circuit board 3 is designed with a notch 10 to center and align the connection device 1 to the microstrip conductor 12 on the printed circuit board 3. The connection device 1 is designed to fit within the notch 10 in the printed circuit board 3.

On both sides of the notch 10 in the printed circuit board 3 are two circular clearance holes 9a, 9b that align with two circular clearance holes 11a, 11b in the connection device 1. Screws 6a, 6b are used to attach through both sets of clearance holes 9a, 9b, 11a, 11b to a mounting surface for the printed circuit board 3. The connection device 1 rests on the ground pads 8a, 8b on the printed circuit board 3 that are grounded to the mounting surface.

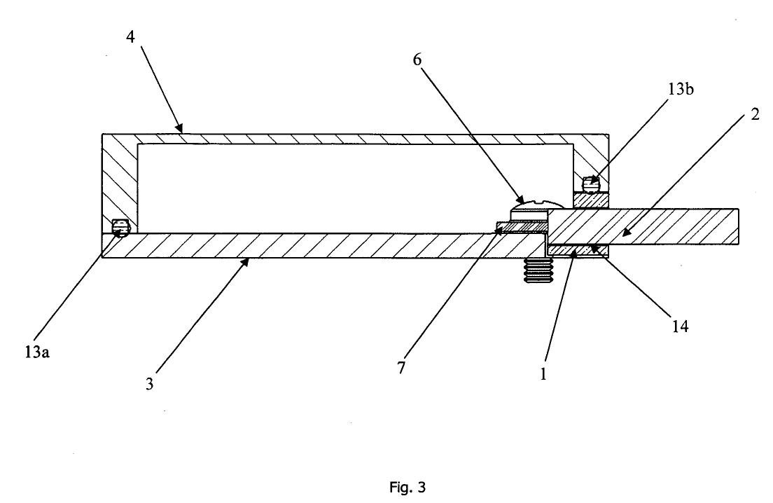

FIG. 3 shows the cross sectional view taken along the centerline of the coaxial cable 2. The interface between the cover 4 and the connection device 1 is an EMI gasket 13b. The EMI gasket 13b rests between the gasket interface 16 of the connection device 1 and the cover interface 5. The EMI gasket 13a, 13b prevents any emissions of the signals on the printed circuit board and emissions into the cavity formed by the cover 4.

The connection device 1 is preferably an integral unit that can be made by machining or casting. Casting is the preferred method for cost reasons. The connection device 1 is solder plated to ground the outer jacket of the coaxial cable 2. When the connection device 1 and coaxial cable are heated, a soldered connection 14 forms between the coaxial cable 2 and the connection device 1.

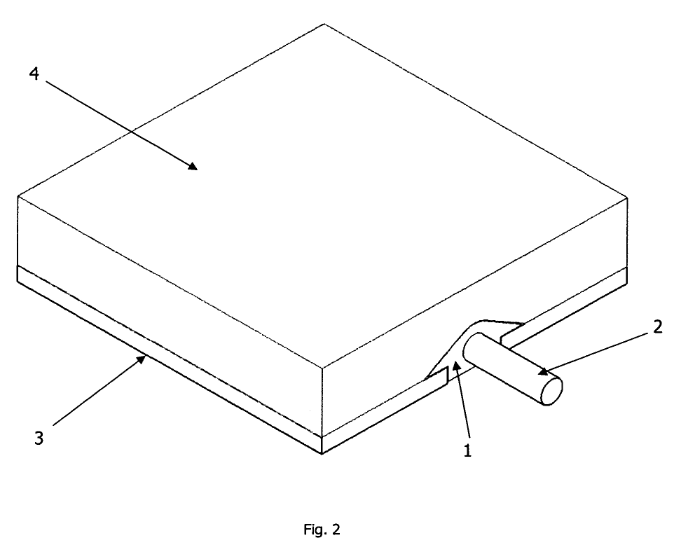

The completed assembly showing the connection device 1, coaxial cable 2, printed circuit board 3 and the cover 4 is shown in FIG. 2.

The present invention is not limited to the example described. The invention can also be used for stripline conductors on a printed circuit board 3. In this instance, the notch 10 in the printed circuit board 3 would be extended to allow for a stripline tab to protrude from the end of the notch 10. The circular hole 15 in the connection device 1 would be adjusted for the height difference of the stripline conductor.

Similarly, other attachment methods for the connection device 1 could be employed. The connection device 1 is designed to be mounted to the printed circuit board 3 using surface mount technology (SMT). The connection device 1 could be hard fitted into the notch 10 in the printed circuit board 3 or held in place with two pins inserted into the clearance holes 9a, 9b of the printed circuit board 3 that would feed through the clearance holes 11a, 11b of the connection device. These methods would restrain the connection device 1 and allow the connection device 1 to be solder reflowed in a similar matter that electronic components are attached to a printed circuit board 3.

In another aspect the present invention further provides a method for assembly and shielding of a coaxial cable and a printed circuit board, comprising the steps of: providing a single piece conductive connector having the circular opening and the outer surface; capturing the coaxial cable within the circular opening of the conductive connector; attaching the connector with the attached coaxial cable to a surface of the printed circuit board; and attaching a cover having integrated metallic shield walls, to the surface of the connector and a surface of the circuit board, to encapsulate and shield radiated emissions from the circuit board and the coaxial cable. Preferably, a conductive gasket is contained within the walls of the cover and the shielding is provided without soldering the walls to the circuit board. Further, attaching the connector comprises use of fasteners or direct solder attachment to a top surface of the printed circuit board.

A number of additional modifications are possible within the scope of the present invention, as will be appreciated by those skilled in the art.

What is claimed is:

1. A device for connecting a coaxial cable to a printed circuit board, the device comprising:
a connector comprising an electrically conductive element having a receptacle that captures an end of the coaxial cable for connecting the coaxial cable to a conductor on the printed circuit board; and
a shield that mates directly to the connector and the printed circuit board, to prevent parasitic radiation.

2. The device of claim 1 wherein the receptacle includes a circular opening for receiving and capturing an end of the coaxial cable.

3. The device of claim 1 wherein the shield comprises a conductive external cover.

4. The device of claim 3 wherein:
the connector includes a surface for interface with the external cover and the cover includes a corresponding surface to receive the connector;
such that when the connector is attached to the circuit board, and the cover is positioned on the printed circuit board and on the connector, the cover forms a cavity around the connector and a circuit on the printed circuit board, to encapsulate radiated emissions.

5. The device of claim 4 wherein the cover shields emissions from electrical signals on the printed circuit board and shields emissions into the cavity formed by the cover.

6. The device of claim 5 further comprising a gasket arrangement including a first EMI gasket between the connector interface surface and said corresponding surface of the cover, to encapsulate emissions from electrical signals on the printed circuit board and emissions into the cavity formed by the cover.

7. The device of claim 6 wherein the gasket arrangement includes a second EMI gasket between the printed circuit board and the cover, thereby encapsulating emissions from electrical signals on the printed circuit board and emissions into the cavity formed by the cover.

8. The device of claim 1 wherein the connector comprises a single piece conductive element.

9. The device of claim 8 wherein the conductive element comprises a conductive metal casting.

10. The device of claim 1 wherein the printed circuit board has a notch to center and align the connector to said conductor on the printed circuit board.

11. The device of claim 10 wherein, when assembled to the printed circuit board, the connector rests on ground pads on the printed circuit board that are grounded.

12. The device of claim 11 wherein the connector attaches to the printed circuit board with fasteners.

13. The device of claim 12 wherein the connector attaches to the printed circuit board by direct solder attachment to the top surface of a printed circuit board.

14. The device of claim 13 wherein the connector is solder plated to ground the outer jacket of the coaxial cable.

15. The device of claim 14 wherein when the connector and coaxial cable are heated, a soldered connection forms between the coaxial cable and the connector.

16. The device of claim 15 wherein the cover is soldered to a ground sink for optimal grounding.

17. A device for connecting a coaxial cable to a printed circuit board, the device comprising:
a connector comprising an electrically conductive element having a circular opening that receives and captures an end of the coaxial cable for connecting the coaxial cable to a conductor on the printed circuit board; and
a shield comprising an external cover that mates directly to the connector and the printed circuit board, to prevent parasitic radiated emission;
the connector further including a surface for interface with the cover and the cover further including a corresponding surface to receive the connector;
such that when the connector is attached to the circuit board, and the cover is positioned on the printed circuit board and on the connector, the cover forms a cavity around the connector and a circuit on the printed circuit board, that shields emissions from electrical signals on the printed circuit board and shields emissions into the cavity formed by the cover.

18. The device of claim 17 further comprising a gasket arrangement including:
a first EMI gasket between the connector interface surface and said corresponding surface of the cover, to encapsulate emissions from electrical signals on the printed circuit board and emissions into the cavity formed by the cover; and
a second EMI gasket between the printed circuit board and the cover, thereby encapsulating emissions from electrical signals on the printed circuit board and emissions into the cavity formed by the cover.

19. The device of claim 18 wherein the conductive element comprises a conductive metal casting, and the printed circuit board has a notch to center and align the connector to said conductor on the printed circuit board, such that when assembled to the printed circuit board, the connector rests on ground pads on the printed circuit board that are grounded.

20. The device of claim 19 wherein the connector is solder plated to ground the outer jacket of the coaxial cable such that when the connector and coaxial cable are heated, a soldered connection forms between the coaxial cable and the connector.

21. A method for assembly and shielding of a coaxial cable and a printed circuit board, comprising the steps of:
providing a single piece conductive connector having a circular opening and an outer surface;
capturing the coaxial cable within the circular opening of the conductive connector;
attaching the connector with attached coaxial cable to a surface of the printed circuit board; and
attaching a cover having integrated metallic shield walls, to the surface of the connector and a surface of the circuit board, to encapsulate and shield radiated emissions from the circuit board and the coaxial cable.

22. The method of claim 21 wherein a conductive gasket is contained within the walls of the cover and the shielding is provided without soldering the walls to the circuit board.

23. The method of claim of claim 21 wherein attaching the connector comprises use of fasteners or direct solder attachment to a top surface of the printed circuit board.
